(19) United States
(12) Patent Application Publication
(10) Pub. No.: US 2026/0339221 A1
(43) Pub. Date: Oct. 29, 2026

(54) EUV MIRROR SYSTEM, METHOD FOR OPERATING AN EUV MIRROR SYSTEM, PROJECTION LENS FOR A MICROLITHOGRAPHIC PROJECTION EXPOSURE APPARATUS, AND COMPUTER PROGRAM PRODUCT

(71) Applicant: Carl Zeiss SMT GmbH, Oberkochen (DE)

(72) Inventors: Carina KURTH, Stuttgart (DE); Matthias FETZER, Stuttgart (DE); Luca METTENLEITER, Neresheim (DE); Julian ZIPS, Bamberg (DE)

(21) Appl. No.: 19/701,241

(22) Filed: Jun. 8, 2026

Related U.S. Application Data
(63) Continuation of application No. PCT/EP2024/083013, filed on Nov. 20, 2024.

(30) Foreign Application Priority Data
Dec. 12, 2023 (DE) 10 2023 212 527.7

(51) Int. Cl. G03F 7/00; G02B 5/08; G02B 7/00

(52) U.S. Cl. CPC G03F 7/70891; G02B 5/0891; G02B 7/008; G03F 7/70033; G03F 7/702; G03F 7/70233; G03F 7/70533; G03F 7/70825

(57) ABSTRACT

An EUV mirror system has an EUV mirror and a load-bearing structure carrying the EUV mirror. The EUV mirror comprises a mirror body and an optical surface on the mirror body. The load-bearing structure has a cooling system for cooling a system component of the EUV mirror system. The cooling system comprises a pump and a cooling channel. The pump conveys a liquid coolant along the cooling channel. The system has a control unit.

### CROSS-REFERENCE TO RELATED APPLICATIONS

The present application is a continuation of, and claims benefit under 35 USC 120 to, international application No. PCT/EP2024/083013, filed Nov. 20, 2024, which claims benefit under 35 USC 119 of German Application No. 10 2023 212 527.7, filed Dec. 12, 2023. The entire disclosure of each of these applications is incorporated by reference herein.

### FIELD

The disclosure relates to an EUV mirror system, to a method for operating an EUV mirror system, to a projection lens for a microlithographic projection exposure apparatus, and to a computer program product.

### BACKGROUND

Microlithography projection exposure apparatuses are utilized for the production of integrated circuits with particularly small structures. In some cases, a photomask illuminated by very short-wave extreme ultraviolet radiation (EUV radiation) is imaged onto a lithography object in order to transfer the mask structure to the lithography object.

The projection exposure apparatus comprises multiple EUV mirrors with optical surfaces from which the radiation is reflected. The mirrors typically have a precisely defined shape and are precisely positioned in order that the imaging of the photomask onto the lithography object is of sufficient quality.

During operation of the projection exposure apparatus, heat is supplied to the mirror body of an EUV mirror, and so the mirror body undergoes heating. The supply of heat arises inter alia from the fact that the EUV radiation incident on the mirror body is not fully reflected but is absorbed to a greater extent. A load-bearing structure that carries the mirror body also undergoes heating, for example as a result of heat exchange with the mirror body or through supply of infrared radiation. In general, temperature changes of a body are accompanied by a thermal deformation. This is usually unwanted in the case of EUV mirrors in a microlithographic projection exposure apparatus because the wavefront of the EUV radiation reflected off the optical surface is often modified when the geometric shape of the mirror changes. Thermal deformation is also typically undesirable in the case of the load-bearing structure of the mirrors, because the positions of the supported mirrors can thus change. This usually leads to a reduction in the imaging quality.

It is possible to use a cooling system in order to keep the temperature of a system component of the EUV mirror system, such as the temperature of the mirror body and/or the temperature of the load-bearing structure, as constant as reasonably possible. A pump of the cooling system can be used to convey a liquid coolant along a cooling channel formed in the system component. The liquid coolant cools the system component by transferring heat from the system component to the liquid coolant in the cooling channel. A higher volume flow of the liquid coolant usually leads to an increased cooling capacity and vice versa. The volume flow of the liquid coolant being kept constant can mean that turbulence in the liquid coolant within the cooling channel can be reduced. Turbulence in the liquid coolant within the cooling channel is generally undesirable because it may pass, in the form of vibrations, onto the mirror body, and this usually leads to a reduction in the imaging quality.

The thermal load acting on the mirror body may change over time, for example if no EUV radiation is incident on the EUV mirror in dark phases or if there is a change in the power of other heat sources. There can be an undesired change in the temperature of the mirror body if the supply of heat changes while the volume flow of the liquid coolant remains constant.

It is possible to monitor the temperature of the mirror body by way of a temperature sensor and to control the cooling capacity by changing the volume flow of the liquid coolant on the basis of a measured temperature change. However, this can be undesirable because typically the change in the volume flow can only be implemented with a time delay, for example after there has already been a change in the temperature of the mirror body. In this case, the change in the volume flow can be implemented quickly so that the undesired change in temperature does not become too large. However, a rapid change in the volume flow means that undesired turbulence may occur. This does not satisfactorily allow the temperature of the mirror body to be kept as constant as reasonably possible while at the same time avoiding undesired turbulence in the liquid coolant.

### SUMMARY

The disclosure seeks to present improvements in an EUV mirror system, a method for operating an EUV mirror system, a projection lens for a microlithographic projection exposure apparatus and a computer program product.

In an aspect, the disclosure provides an EUV mirror system comprising an EUV mirror, a load-bearing structure, a cooling system for cooling a system component of the EUV mirror system, and a control unit. The EUV mirror has a mirror body and an optical surface formed on the mirror body. The load-bearing structure carries the EUV mirror. The cooling system comprises a pump and a cooling channel. The pump is designed to convey a liquid coolant along the cooling channel. The control unit is supplied with an input variable representing a thermal load acting on the system component. The control unit processes the input variable and a thermal model of the system component in order to determine a target value for the volume flow of the liquid coolant. The control unit derives a control command for the cooling system from the target value for the volume flow such that the volume flow is adjusted and such that a predetermined maximum rate of change of the volume flow is not exceeded. The cooling system is controlled by way of the control command such that the cooling system influences the volume flow on the basis of the control command.

Rather than only reacting to a change in temperature of the system component that has already arisen, the disclosure proposes to build on a change in a thermal load acting on the system component. The influence of the change on the temperature of the system component can be predicted using a thermal model, and the volume flow of the liquid coolant can be set on the basis of the prediction. The thermal load acting on a system component can change abruptly, for example if the EUV radiation is switched off to allow for a change of the wafer or of the photomask. Conventional control can result in a correspondingly rapid change in the volume flow. The disclosure has recognized that the time gained by the prediction can allow the change in the volume flow to be extended in time without this resulting in an excessive temperature change of the system component. This can lead to a proposal according to the disclosure of predetermining a maximum rate of change for the volume flow and controlling the cooling system such that this maximum rate of change is not exceeded. As a result, it is possible to react to a change in the heat state of the mirror body without exciting undesired vibrations of the mirror body.

In one embodiment, the system component is the mirror body of the EUV mirror. The cooling channel may extend within the mirror body. In another embodiment, the system component is the load-bearing structure that carries the EUV mirror. The cooling channel may extend within the load-bearing structure. The disclosure also encompasses embodiments in which the mirror body is provided with a cooling channel and the load-bearing structure is provided with a cooling channel and in which the volume flow in the cooling channel of the mirror body and the volume flow in the cooling channel of the load-bearing structure are set according to the disclosure.

The heat source of the thermal load acting on the mirror body may be the EUV radiation that is incident on the optical surface of the mirror and at least partially absorbed. In that case, the change in the thermal load acting on the mirror body may result from the fact that no EUV radiation is incident on the optical surface of the mirror body during a dark phase.

Another heat source can be a heating device used to supply thermal energy to the mirror body. For example, the heating device may be designed to guide suitable electromagnetic radiation, such as infrared radiation, to the mirror body. The heating device can heat the mirror body uniformly, for example in a preheating phase that precedes the operation of the projection exposure apparatus. It is also possible for the heating device to be designed as a sector heater which only heats certain regions of the mirror body (in sector specific fashion). For example, a sector heater can be used to supply heat to those regions of the mirror body that are only heated to a lesser extent by EUV radiation.

A change in the thermal load acting on the mirror body may then result from the heating device being switched on or off, from the heating device switching between uniform and sector-specific heating of the mirror body, or from changes in the power of the electromagnetic radiation guided by the heating device to the mirror body. The load-bearing structure that carries the mirror body and exchanges heat with the mirror body can form a further heat source. The change in the thermal load acting on the mirror body can then result from the change in the heat that is absorbed or emitted by the load-bearing structure itself.

For example, a change in the thermal load acting on the load-bearing structure may result from changes in the thermal radiation reflected off other system components or from changes in the amount of heat emitted by another system component. For example, a consequence of the EUV radiation being switched off is that the mirror body emits less heat. It is also possible for there to be changes in the power of a heating device directed at the load-bearing structure.

The input variable representing a thermal load acting on the system component may be a binary value relating to the activity of a heat source. For example, the value 0 may indicate that the heat source does not transfer any thermal energy to the system component, and the value 1 may indicate that the heat source transfers thermal energy to the system component. In an embodiment, the input variable is a value relating to the amount of thermal energy transferred from the heat source to the system component. The input variable can be a time-dependent value and/or a value for a specific time. For example, the input variable may comprise information regarding a future time at which a thermal load acting on the system component changes, i.e. at which, for example, the EUV radiation incident on the optical surface of the mirror will be eliminated. The input variable may also comprise multiple such values.

The thermal model of the mirror body may be chosen such that it establishes a relationship between the thermal load acting on the system component and the temperature of the system component such that future temperature values of the mirror body can be predicted. For example, the density, thermal conductivity and/or specific heat capacity of the material of the system component can be taken into account in the thermal model. For example, the thermal model may be obtained by a method of machine learning. The thermal model may take heat transfer between the mirror body and the load-bearing structure into account.

In one embodiment, the control unit processes the input variable and the thermal model in order to determine a future temperature value of the system component, assuming that the volume flow of the coolant is kept constant at its current value. In other words, in that case the control unit predicts the future profile of the temperature of the mirror body at a constant volume flow. The temperature value may be above or below the current temperature of the mirror body or may correspond thereto. On the basis of the difference between the future temperature value thus determined and a target value for the temperature of the system component, the control unit can determine a target value for the cooling capacity used to keep the temperature of the mirror body constant. The control unit can then determine the target value profile for the volume flow on the basis of the target value for the cooling capacity of the cooling system. For example, the control unit can use information such as the nature of the liquid coolant or a relationship between the rotational speed of the pump and the volume flow of the liquid coolant for this purpose. There are multiple variants for performing the method in practice. For example, the control unit may be designed to perform the relevant calculations online in each case before a new control command is transmitted. It is also possible to store relationships once determined in a table and to generate the control commands on the basis of values read from the table.

The maximum rate of change relates to the change in the volume flow with which the volume flow can be guided to the target value. Starting from the actual value of the volume flow, there can be a transition phase in which the volume flow changes. The volume flow can correspond to the target value at the end of the transition phase. In general, at no point during the transition phase does the rate of change of the volume flow exceed the predetermined maximum rate of change. The duration of the transition phase may be between, e.g., 10 seconds and 500 seconds, such as between 30 seconds and 300 seconds. The duration of the transition phase can help ensure that it is possible to predetermine a sufficiently smooth control trajectory, along which the volume flow cam be controlled from the actual value to the target value of the volume flow without undesired vibrations of the mirror body being excited.

The maximum rate of change of the volume flow may be predetermined in such a way that, on the one hand, the target value of the volume flow is reached as quickly as reasonably possible, while, on the other hand, the transition phase is sufficiently long that no significant vibrations of the system component are excited. The maximum rate of change can also result from the profile of a predetermined control trajectory for the transition from the actual value of the volume flow to the target value of the volume flow. The control trajectory is desirable if it does not contain any frequencies that lead to undesired vibrations of the mirror body. It is also desirable if the control trajectory satisfies the system dynamics such that the volume flow is physically capable of satisfying the control trajectory. For example, the value of the maximum rate of change resulting from these desired properties may be determined by experimentation or by simulation. For example, the predetermined maximum rate of change of the volume flow may be less than 30%/min, such as less than 20%/min, for example less than 10%/min.

In one embodiment, the transition from the actual value of the volume flow to the target value of the volume flow is performed at a constant rate of change, which corresponds to the predetermined maximum rate of change. In that case, the predetermined maximum rate of change can define a type of ramp along which the volume flow is transferred from the actual value to the new target value. Embodiments in which the rate of change changes during the transition are also possible. In this case, the transition may comprise sections during which the rate of change is lower than the predetermined maximum rate of change, but no sections in which the rate of change exceeds the predetermined maximum rate of change. The transition may be such that the second derivative of the rate of change also does not exceed a predetermined maximum value. This can help make it possible to make a further contribution to avoiding flow-induced vibrations.

In one embodiment, a control trajectory is predetermined for the transition from the actual value of the volume flow to the target value of the volume flow. The control trajectory may be nonlinear. The control trajectory being nonlinear means that abrupt changes in the volume flow can be avoided, especially at the beginning and at the end of the control. For example, the control trajectory may correspond to a sigmoid or S-curve. If the volume flow follows the control trajectory, then the predetermined maximum rate of change of the volume flow is not exceeded. For example, the control trajectory is chosen such that its steepest point corresponds to a change in the volume flow that is less than or equal to the predetermined maximum rate of change. The control trajectory may be chosen such that a dead time used by the cooling system to reach the target value of the volume flow is taken into account. For example, the dead time can have its origin in the inertia of the pump or the liquid coolant. In other words, the boundary conditions of the maximum rate of change and the dead time may limit the selection of possible control trajectories.

Control commands for the pump of the cooling system can be derived from an envisaged transition from the actual value of the volume flow to the target value of the volume flow such that the pump is actuated in accordance with the desired transition. For example, the rotational speed of the pump can be controlled on the basis of the control trajectory and hence the volume flow can be influenced accordingly. The liquid coolant may be water or other fluid coolants customary in the industry.

The mirror system may comprise a temperature sensor in order to determine a measured temperature value of the system component. The temperature sensor may be formed on the system component. The measured temperature value may be supplied to the control unit. For this purpose, the temperature sensor may be connected to the control unit via an information line. The measured temperature value can be processed in the control unit in order to detect and compensate for control errors. For example, the control error may result from the difference between a predicted temperature value and a measured temperature value.

The control unit may comprise a memory block in which, inter alia, the thermal model and the maximum rate of change of the volume flow can be stored. It is also possible for relationships between specific changes in a thermal load and associated control commands for the pump to be stored in tabular form in the memory block.

The cooling system can influence the volume flow by changing the rotational speed of the pump. For this purpose, the pump may be controlled by the control unit via a control line using the control command, for example. It is also possible for the cooling system to comprise valves or slides actuated by the control unit in order to influence the volume flow.

The cooling system may comprise a first cooling channel, which is formed in the mirror body, and a second cooling channel, which is formed in a load-bearing structure that carries the mirror body. The cooling system may also comprise a first cooling structure of a plurality of cooling channels, which is formed in the mirror body, and a second cooling structure of a plurality of cooling channels, which is formed in a load-bearing structure that carries the mirror body. The second cooling channel may be connected to the first cooling channel. The disclosure may also be used to keep the temperature of the load-bearing structure that carries the mirror body as constant as reasonably possible.

In an aspect, the disclosure provides a projection lens comprising a plurality of EUV mirrors used to image a photomask into an image plane. One or more EUV mirrors of the projection lens may be configured as a constituent part of an EUV mirror system according to the disclosure. In an aspect, the disclosure provides a microlithographic projection exposure apparatus having such a projection lens.

In an aspect, the disclosure provides a method for operating a mirror system having an EUV mirror, wherein the EUV mirror comprises a mirror body and an optical surface formed on the mirror body, and having a load-bearing structure that carries the EUV mirror. A liquid coolant is conveyed via a pump of a cooling system along a cooling channel formed within a system component of the EUV system in order to cool the system component. An input variable representing a thermal load acting on the system component is supplied to a control unit. The control unit processes the input variable and a thermal model of the system component in order to determine a target value for the volume flow of the liquid coolant, wherein the control unit derives a control command for the cooling system from the target value for the volume flow such that the volume flow is adjusted and a predetermined maximum rate of change of the volume flow is not exceeded, and wherein the cooling system is controlled by way of the control command.

In an aspect, the disclosure provides a computer program product or a set of computer program products comprising program parts which, when loaded into a computer or into networked computers connected to a device according to the disclosure, are designed to perform the method according to the disclosure.

The disclosure encompasses developments of the EUV mirror system with features that are described in the context of the method according to the disclosure. The disclosure encompasses developments of the method with features that are described in the context of the EUV mirror system according to the disclosure.

### BRIEF DESCRIPTION OF THE DRAWINGS

The disclosure is described by way of example below on the basis of certain embodiments and with reference to the accompanying drawings, in which:

FIG. 1: shows an embodiment of a projection exposure apparatus according to the disclosure;

FIG. 2: shows a schematic illustration of an EUV mirror system according to the disclosure;

FIG. 3: shows a schematic illustration of an EUV mirror system according to the disclosure;

FIG. 4: shows a schematic plot of the temperature of a mirror body of the EUV mirror system over time for a constant volume flow of the liquid coolant;

FIG. 5: shows a schematic plot of a control trajectory according to the disclosure over time;

FIG. 6: shows a temperature profile of the mirror body over time;

FIG. 7: shows a schematic illustration of a mirror system according to the disclosure; and

FIG. 8: shows a schematic illustration of an EUV mirror system according to the disclosure.

### DETAILED DESCRIPTION

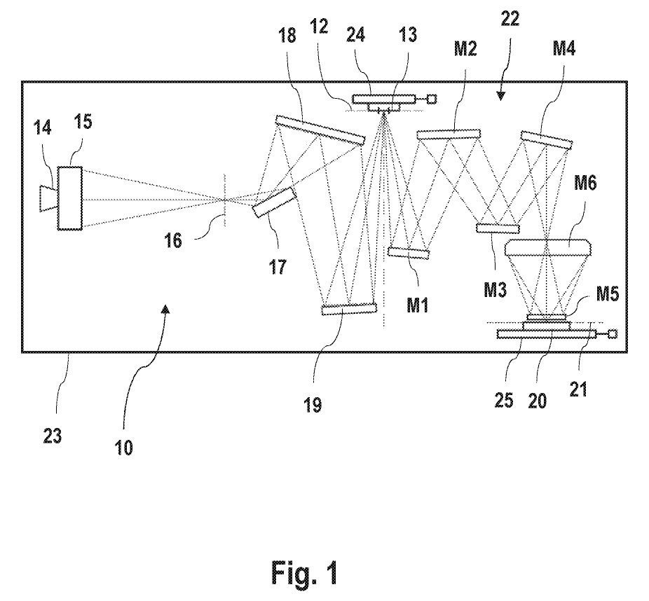

FIG. 1 schematically illustrates a microlithographic EUV projection exposure apparatus. The projection exposure apparatus comprises an exposure beam source 14, an illumination system 10 and a projection lens 22, which are operated jointly in a vacuum chamber 23. The vacuum chamber 23 is under negative pressure during the operation of the EUV projection exposure apparatus.

The exposure beam source 14 generates electromagnetic radiation in the EUV range, i.e. at a wavelength between 5 nm and 30 nm for example. The exposure radiation emanating from the exposure beam source 14 is focused into an intermediate focal plane 16 by way of a collector 15. Exposure radiation passing across the intermediate focal plane 16 is guided into an object plane 12 by the illumination system 10, with the result that an object field in the object plane 12 is illuminated with uniform radiation intensity.

The illumination system 10 comprises a deflection mirror 17 used to deflect the exposure radiation to a first facet mirror 18. A second facet mirror 19 is disposed downstream of the first facet mirror 18. The second facet mirror 19 is used to image the facets of the first facet mirror 18 into the object plane 12.

A photomask 13 is arranged in the object plane 12 and is imaged into an image plane 21 by way of a plurality of mirrors M1-M6 of the projection lens 22. A structure formed on the photomask 13 is transferred to a radiation-sensitive layer of a wafer 20 arranged in the image plane 21. The photomask 13 is suspended from a first scanning device 24, and the wafer 20 is at rest on a second scanning device 25 such that the wafer 20 can be exposed in a scanning procedure during which the photomask 13 and the wafer 20 are moved synchronously with one another.

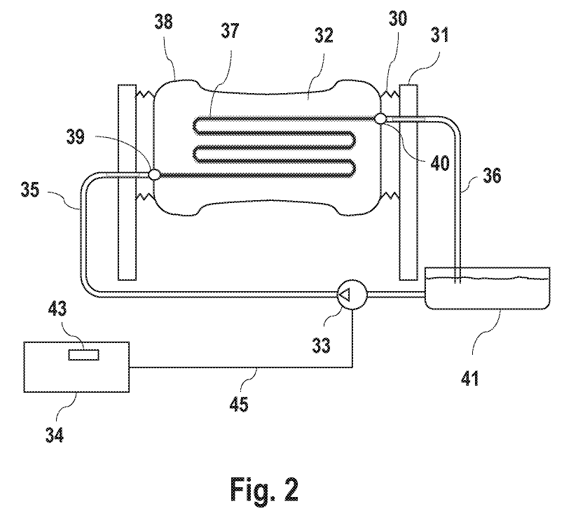

FIG. 2 shows a mirror device, in which a mirror body 38 of a mirror M1-M6 is held on a load-bearing structure 31 via actuators 30. The actuators 30 can be used to alter the position of the mirror body 38 relative to the load-bearing structure 31 for the purpose of orienting and positioning the mirror body 38. An optical surface 32 off which EUV radiation is reflected is formed on the mirror body 38. Each of the mirrors M1-M6 of the projection lens 22 from the projection exposure apparatus of FIG. 1 is in the form of a mirror device according to FIG. 2. It is also possible to equip only some of the mirrors M1-M6 in this way.

A cooling channel 37, which extends through the mirror body 38 along a serpentine path in this embodiment, is formed in the interior of the mirror body 38. The cooling channel 37 is part of a cooling system in which a liquid coolant is conveyed along a closed cooling circuit via a pump 33.

In the embodiment shown, the cooling circuit extends from the pump 33 through a feed line 35 to the cooling channel 37 and, through a return line 36, back to a storage container 41, from where the liquid coolant is aspirated by the pump 33. The feed line 35 is connected to the mirror body 38 via an input connector 39; the return line 36 is connected to the mirror body 38 via an output connector 40. The feed line 35 and the return line 36 have sufficient flexibility so that adjustment and alignment of the mirrors are not impeded. The liquid coolant absorbs heat resulting from the absorbed EUV radiation and dissipates this heat from the mirror body 38.

The mirror system comprises a control unit 34 which controls the mirror system operation on the basis of various input variables, wherein control commands inter alia influence the thermal state of the mirror body 38. One aspect here is that the control unit 34 actuates the pump 33 of the cooling system using control commands such that the pump 33 influences the volume flow of the liquid coolant on the basis of the control command by changing its rotational speed.

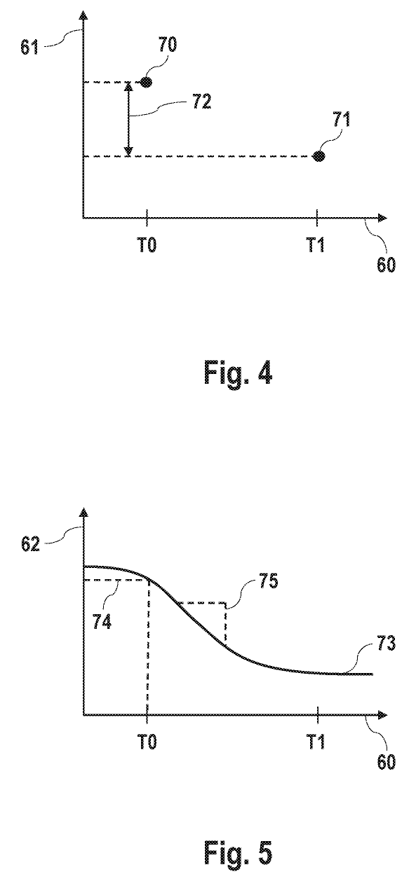

The temperature of the mirror body 38 remains constant if the cooling capacity of the cooling system corresponds to the supplied thermal power. The mirror body 38 is cooled if a thermal load is eliminated while the state of the cooling system remains unchanged. For this case, FIG. 4 shows a schematic plot of the temperature 61 of the mirror body, plotted over a time axis 60. A change in a thermal load acting on the mirror body occurs at time T0. More precisely, the thermal load acting on the mirror body as a result of the EUV radiation is eliminated at time T0 in the present example, and so less heat overall is supplied to the mirror body. Since the volume flow of the liquid coolant remains unchanged, a future temperature value 71 at a future time T1 is below the temperature value 70 at the time T0 when the thermal load is eliminated. In other words, the cooling system cools the mirror body after the thermal load has been eliminated, and this leads to an undesired change in temperature 72.

In order to counteract this, the control unit 34 in the present exemplary embodiment processes information about the fact that a thermal load will be eliminated at the time T0 as an input variable and predicts the future temperature value 71 on the basis of a thermal model. The thermal model is stored in a memory block 43. The control unit 34 then determines a target value for the cooling capacity of the cooling system on the basis of the predicted temperature value 71. The target value for the cooling capacity is determined such that the temperature of the mirror body 38 is kept as constant as reasonably possible. In this example, the cooling capacity is reduced in order to compensate for the elimination of the thermal load. The control unit 34 then establishes a relationship between the target value for the cooling capacity and a target value, resulting therefrom, for the volume flow of the liquid coolant in order to determine a control command for the pump 33. In this example, the volume flow of the liquid coolant is reduced in order to reduce the cooling capacity.

In the present exemplary embodiment, the determined control command has the effect that the rotational speed 62 of the actuated pump 33 follows a control trajectory 73. FIG. 5 shows a schematic plot of the control trajectory 73, plotted here over a time axis 60. In this example, the control trajectory 73 is a nonlinear S-curve that reduces the rotational speed 62 of the pump 33 over time. By virtue of the control trajectory being nonlinear, abrupt changes in the rotational speed 62 of the pump 33 are avoided, such as at the beginning and at the end of the control, and undesired turbulence in the liquid coolant is thus prevented. As a result of the control trajectory 73, the reduction in the rotational speed 62 of the pump 33 already starts in a time period 74 shortly before the time T0 when the thermal load is eliminated. This is possible because, as an input variable, the control unit 34 has processed the information that the thermal load will be eliminated at the time T0. As a result, it is possible to choose a flatter S-curve as the control trajectory and to observe a predetermined maximum rate of change 75, which results from a predetermined maximum rate of change of the volume flow, in order to avoid undesired turbulence. In other words, the time period 74 is used to start the control already before the time T0. With the time period 74, the control trajectory 73 also takes into account the inertia of the pump, i.e. a dead time of the cooling system.

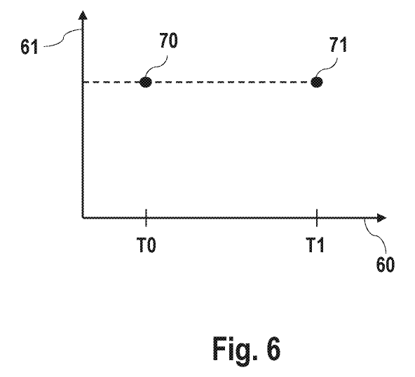

FIG. 6 shows an idealized plot of the temperature 61 of the mirror body in the case of volume flow control according to the disclosure, plotted over a time axis 60. A change in a thermal load acting on the mirror body occurs at the time T0. As a result of the volume flow control on the basis of the control trajectory 73, the temperature 61 remains constant over time, and so no undesired temperature change occurs.

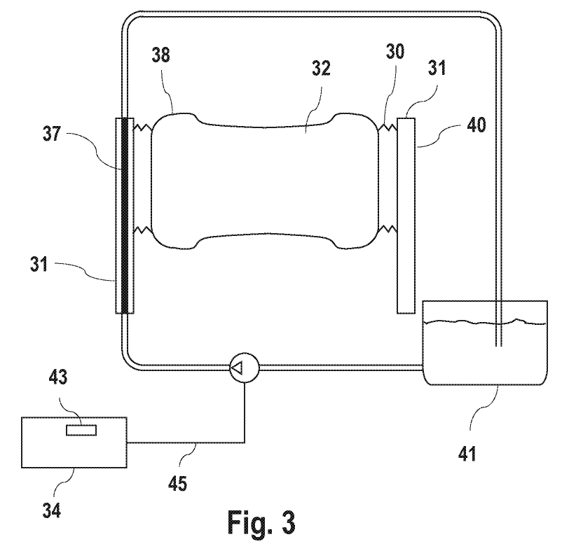

FIG. 3 shows a schematic illustration of a further EUV mirror system according to the disclosure, in which the cooling channel 37 extends through the load-bearing structure 31. In this case, the control unit 34 influences the thermal state of the load-bearing structure 31 using the control commands. The control commands are determined by the control unit 34 in a manner similar to the previous embodiment.

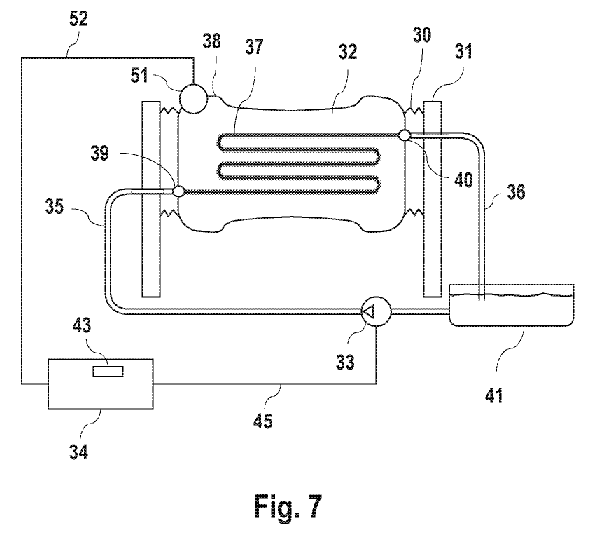

FIG. 7 shows a schematic illustration of a mirror system with feedback. The feedback consists in a temperature sensor 51 determining a measured temperature value of the mirror body and transmitting this to the control unit 34 via an information line 52. The control unit 34 recognizes a control error on the basis of the measured temperature value and adjusts the determined control trajectory 73 in order to compensate for the control error.

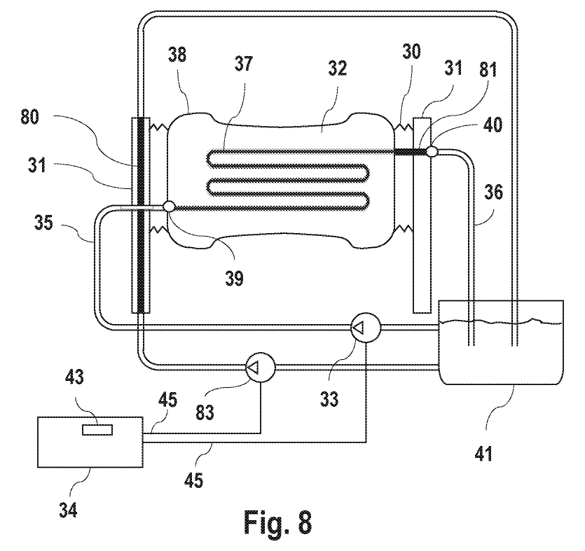

FIG. 8 shows a schematic illustration of a further EUV mirror system according to the disclosure, having a first cooling channel 37, which is formed in the mirror body 38, a second cooling channel 80, which is formed in a load-bearing structure 31 that carries the mirror body, and a third cooling channel 81, which is formed in a further load-bearing structure 31 that carries the mirror body. The first cooling channel 37 is connected to the third cooling channel 81. A second pump 83 is assigned to the second cooling channel 80. Like the pump 33, the second pump 83 is actuated by control commands which are determined by the control unit 34.

What is claimed is:

1. A system, comprising:
an EUV mirror comprising a mirror body and an optical surface supported by the mirror body;
a load-bearing structure supporting the EUV mirror;
a cooling system a cooling channel and a pump configured to convey a liquid coolant along the cooling channel; and
a control unit,
wherein:
the cooling system is configured to cool at least one member selected from the group consisting of the EUV mirror and the load-bearing structure;
the EUV mirror system is configured to supply to the control unit an input variable representing a thermal load acting on the member;
the control unit configured to process the input variable and a thermal model of the member to determine a target value for a volume flow of the liquid coolant;
the control unit is configured to derive a control command for the cooling system from the target value for the volume flow so that the volume flow is adjustable and so that a maximum rate of change of the volume flow is not exceeded; and
the control unit is configured to control the cooling system via the control command.

2. The system of claim 1, wherein the member comprises the mirror body, and wherein the cooling channel extends within the mirror body.

3. The system of claim 1, wherein the member comprises the load-bearing structure, the cooling channel extends within the load-bearing structure.

4. The system of claim 1, wherein the thermal model of the member is configured to provide a relationship between the thermal load acting on the member and a temperature of the member, and the thermal model is applicable to predict a future temperature value of the member.

5. The system of claim 1, wherein the control unit is configured to determine the target value for the volume flow from a target value for a cooling capacity of the cooling system.

6. The system of claim 1, wherein the input variable represents a future change in a thermal load acting on the member.

7. The system of claim 1, wherein the thermal model takes into account heat transfer between the mirror body and the load-bearing structure.

8. The system of claim 1, wherein the cooling system is configured to influence the volume flow on the basis of the control command such that the volume flow follows a control trajectory.

9. The system of claim 8, wherein the control trajectory is nonlinear.

10. The system of claim 8, wherein a steepest point of the control trajectory corresponds to a rate of change in the volume flow that is less than or equal to the maximum rate of change.

11. The system of claim 1, wherein a heat source of the thermal load is EUV radiation incident on the optical surface of the mirror, a heating device, and/or the load-bearing structure.

12. The system of claim 1, further comprising a temperature sensor configured to determine a measured temperature value of the member, wherein the measured temperature value is suppliable to the control unit to determine a control error.

13. The system of claim 1, wherein the system comprises a microlithographic projection lens configured to image an object in an object plane into an image plane, and the microlithographic projection lens comprises the EUV mirror.

14. The system of claim 1, wherein the system comprises a microlithographic projection exposure system, the microlithographic projection exposure system comprises a microlithographic projection lens configured to image an object in an object plane into an image plane, and the microlithographic projection lens comprises the EUV mirror.

15. A method of operating a system comprising an EUV mirror, a load-bearing structure supporting the EUV mirror and a cooling channel, the method comprising:
determining a target flow for a volume flow of liquid coolant in the cooling channel based on: i) an input variable representing a thermal load acting on a member selected from the group consisting of the EUV mirror and the load-bearing structure; ii) and a thermal model of the member;
based on the target flow, adjusting the volume flow of the liquid coolant in the cooling channel without exceeding a predetermined maximum rate of change of the volume flow of the liquid coolant in the channel.

16. The method of claim 15, wherein the thermal model provides a relationship between the thermal load acting on the member and a temperature of the member, and the thermal model is used to predict a future temperature value of the member.

17. The method of claim 15, comprising determining the target value for the volume flow from a target value for a cooling capacity of the cooling system.

18. The method of claim 15, wherein the input variable represents a future change in a thermal load acting on the member, and/or the thermal model takes into account heat transfer between the mirror body and the load-bearing structure.

19. One or more machine-readable hardware storage devices comprising instructions that are executable by one or more processing to perform the method of claim 1.

20. A system, comprising:
one or more processing devices; and
one or more machine-readable hardware storage devices comprising instructions that are executable by the one or more processing to perform the method of claim 1.
